(19) United States
(12) Patent Application Publication
(10) Pub. No.: US 2022/0352270 A1
(43) Pub. Date: Nov. 3, 2022

(54) DISPLAY DEVICE

(71) Applicant: Samsung Display Co., Ltd., Yongin-si (KR)

(72) Inventors: SOYOUNG LEE, Asan-si (KR); SEUNGWOO SUNG, Cheonan-si (KR); IL GOO YOUN, Asan-si (KR)

(21) Appl. No.: 17/693,589

(22) Filed: Mar. 14, 2022

(30) Foreign Application Priority Data
May 3, 2021 (KR) 10-2021-0057084

(51) Int. Cl. H01L 27/32; H01L 51/52

(52) U.S. Cl. CPC H01L 27/3246; H01L 51/5209; H01L 51/5284; H01L 27/3258

(57) ABSTRACT

A display device includes: a first transistor; an insulating layer disposed on the first transistor; a first pixel electrode which is connected to the first transistor and disposed on the insulating layer and defines a first opening exposing the insulating layer therein; a pixel defining layer disposed on the first pixel electrode and defining a plurality of second openings exposing the first pixel electrode therein; and a first light emitting layer disposed on the pixel defining layer to fill the plurality of second openings.

This application claims priority to Korean Patent Application No. 10-2021-0057084, filed on May 3, 2021, and all the benefits accruing therefrom under 35 U.S.C. § 119, the content of which in its entirety is herein incorporated by reference

### BACKGROUND

### 1. Technical Field

Embodiments relate to a display device. More particularly, embodiments relate to a display device including a plurality of pixels.

### 2. Description of the Related Art

A flat panel display device is being used as a display device that replaces a cathode ray tube display due to characteristics such as light weight and thinness. Representative examples of such flat panel display device include a liquid crystal display device and an organic light emitting display device.

In general, the display device is manufactured to implement a wide viewing angle, but it may be desirable to temporarily implement a display device with a narrow viewing angle so that no one other than an user can see the screen in a public place.

### SUMMARY

Embodiments may provide a display device including a plurality of pixels.

A display device according to an embodiment includes: a first transistor; an insulating layer disposed on the first transistor; a first pixel electrode which is connected to the first transistor and disposed on the insulating layer and defines a first opening exposing the insulating layer therein; a pixel defining layer disposed on the first pixel electrode and defining a plurality of second openings exposing the first pixel electrode therein; and a first light emitting layer disposed on the pixel defining layer to fill the plurality of second openings.

In an embodiment, the pixel defining layer may be disposed to fill the first opening.

In an embodiment, the display device may further include: a second transistor; a second pixel electrode connected to the second transistor and disposed on the insulating layer disposed on the second transistor, where the second pixel electrode does not define an opening exposing the insulating layer therein; and a second light emitting layer disposed on the second pixel electrode.

In an embodiment, the pixel defining layer may be disposed on the second pixel electrode, and may define a third opening exposing the second pixel electrode therein, and the second light emitting layer may be disposed in the third opening

In an embodiment, the first light emitting layer and the second light emitting layer may emit light of the same color, and a size of an area in which the first light emitting layer contacts the first pixel electrode may be the same as a size of an area in which the second light emitting layer contacts the second pixel electrode.

In an embodiment, the display device may further include: a common electrode disposed on the first light emitting layer and the second light emitting layer, and an encapsulating layer disposed on the common electrode.

In an embodiment, areas in which the first pixel electrode and the first light emitting layer contact may form light emitting areas, and the display device may further include a light blocking pattern disposed to expose the light emitting areas in a plan view

In an embodiment, the light blocking pattern may be disposed to overlap the first opening in the plan view.

In an embodiment, the light emitting areas may emit light of the same color.

In an embodiment, the display device may further include: a second transistor; a second pixel electrode which is connected to the second transistor and disposed on the insulating layer disposed on the second transistor and define a third opening exposing the insulating layer therein; and a second light emitting layer disposed on the second pixel electrode.

In an embodiment, the pixel defining layer may be disposed on the second pixel electrode and may define a plurality of fourth openings exposing the second pixel electrode therein, and the second light emitting layer may be disposed to fill the fourth openings.

In an embodiment, the pixel defining layer may be disposed to fill the third opening.

In an embodiment, the first light emitting layer and the second light emitting layer may emit light of the same color.

In an embodiment, the first light emitting layer and the second light emitting layer may emit light of different colors.

In an embodiment, the first pixel electrode may receive a signal for driving the first light emitting layer from the first transistor.

In an embodiment, the first opening may have a polygonal shape or a circular shape in the plan view.

In an embodiment, the first opening may have a cross shape in the plan view.

In an embodiment, the first opening may have a shape extending in one direction in the plan view.

In an embodiment, the first opening may be provided in plural.

A display device according to embodiments of the present invention may include a first transistor, an insulating layer disposed on the first transistor, a first pixel electrode which is connected to the first transistor and disposed on the insulating layer and defines a first opening exposing the insulating layer, a pixel defining layer disposed on the first pixel electrode and defining a plurality of second openings exposing the first pixel electrode, and a first light emitting layer disposed on the pixel defining layer to fill the plurality of second openings.

A gas emitted in a process of forming the insulating layer and the pixel defining layer (e.g., a baking process) may be effectively discharged through the first opening. Accordingly, defects caused by the pressure caused by the gas may be effectively reduced.

### BRIEF DESCRIPTION OF THE DRAWINGS

Illustrative, non-limiting embodiments will be more clearly understood from the following detailed description taken in conjunction with the accompanying drawings.

FIG. 1 is a block view illustrating a display device according to an embodiment.

FIG. 2 is a plan view illustrating an embodiment of pixels disposed on a display panel of the display device of FIG. 1.

FIGS. 3, 4 and 5 are plan views illustrating other embodiments of pixels disposed on a display panel of the display device of FIG. 1.

FIG. 6 is a cross-sectional view showing an embodiment taken along line I-I′ of FIG. 2.

FIG. 7 is a cross-sectional view showing an embodiment taken along line I-I′ of FIG. 2.

FIG. 8 is a cross-sectional view showing an embodiment taken along line I-I′ of FIG. 2.

FIG. 9 is a cross-sectional view showing an embodiment taken along line II-II′ of FIG. 2.

FIG. 10 is a cross-sectional view showing an embodiment taken along line of FIG. 3.

FIG. 11 is a block view illustrating an electronic device according to an embodiment.

FIG. 12 is a diagram view an example in which the electronic device of FIG. 11 is implemented as a television.

FIG. 13 is a diagram illustrating an example in which the electronic device of FIG. 11 is implemented as a smartphone.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, display devices in accordance with embodiments will be explained in detail with reference to the accompanying drawings.

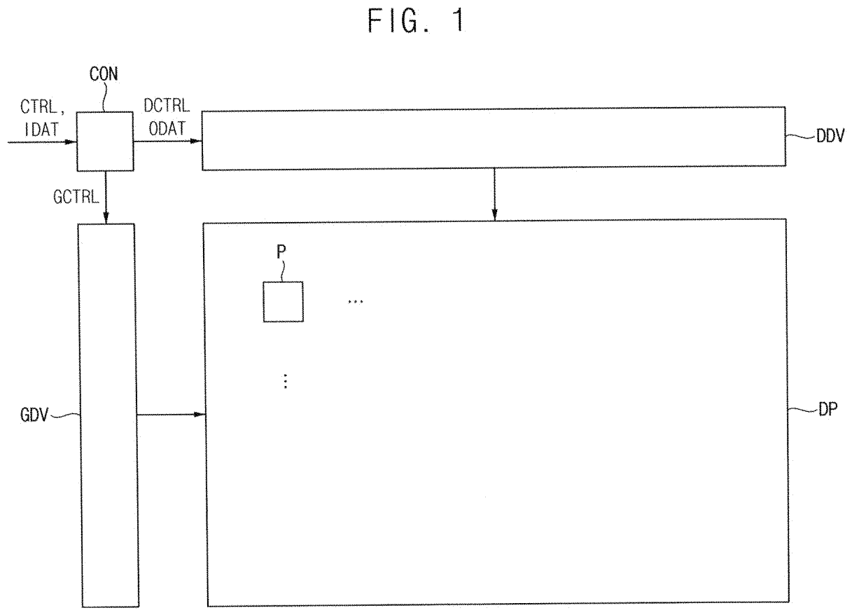

FIG. 1 is a block view illustrating a display device according to an embodiment.

Referring to FIG. 1, The display device may include a display panel DP, a data driver DDV, a gate driver GDV, and a timing controller CON.

The display device may display an image through the display panel DP. To this end, the display panel DP may include a plurality of pixels P. Each of the plurality of pixels P may include a light emitting element and element for driving the light emitting element (e.g., a transistor, a capacitor, etc.). Each of the pixels P may include a plurality of sub-pixels. The pixels P may be entirely disposed in the display panel DP. For example, the pixels P may be arranged in a matrix form in the display panel DP.

The pixels P may include a plurality of sub-pixels. For example, one pixel P may include one red sub-pixel, one blue sub-pixel, and one green sub-pixel. Alternatively, one pixel P may include one red sub-pixel, one blue sub-pixel, and two green sub-pixels. The plurality of sub-pixels may be arranged in a matrix form, a PENTILE™ form, an S-stripe form, or the like.

In embodiments, the display panel DP may be configured as a single panel. Alternatively, in embodiments, the display panel DP may be configured by connecting a plurality of panels.

The timing controller CON may generate a gate control signal GCTRL, a data control signal DCTRL, and an output image data ODAT based on a control signal CTRL and an input image data IDAT provided from an outside. there is. For example, the control signal CTRL may include a vertical synchronization signal, a horizontal synchronization signal, an input data enable signal, a master clock signal, and the like. For example, the input image data IDAT may be RGB data including red image data, green image data, and blue image data. Alternatively, the input image data IDAT may include magenta image data, cyan image data, and yellow image data.

The gate driver GDV may generate gate signals based on the gate control signal GCTRL provided from the timing controller CON. For example, the gate control signal GCTRL may include a vertical start signal, a clock signal, and the like. In embodiments, the gate driver GDV may be manufactured as a separate panel and connected to the display panel DP. The gate driver GDV may be electrically connected to the display panel DP and sequentially output the gate signals. Each of the pixels P may receive a data signal according to control of each of the gate signals.

The data driver DDV may generate the data signal based on the data control signal DCTRL and the output image data ODAT provided from the timing controller CON. For example, the data control signal DCTRL may include an output data enable signal, a horizontal start signal, a load signal, and the like. In embodiments, the data driver DDV may be manufactured as a separate panel and may be electrically connected to the display panel DP. The data driver DDV may be electrically connected to the display panel DP and may generate a plurality of data signals. Each of the pixels P may display an image with a luminance corresponding to each of the data signals.

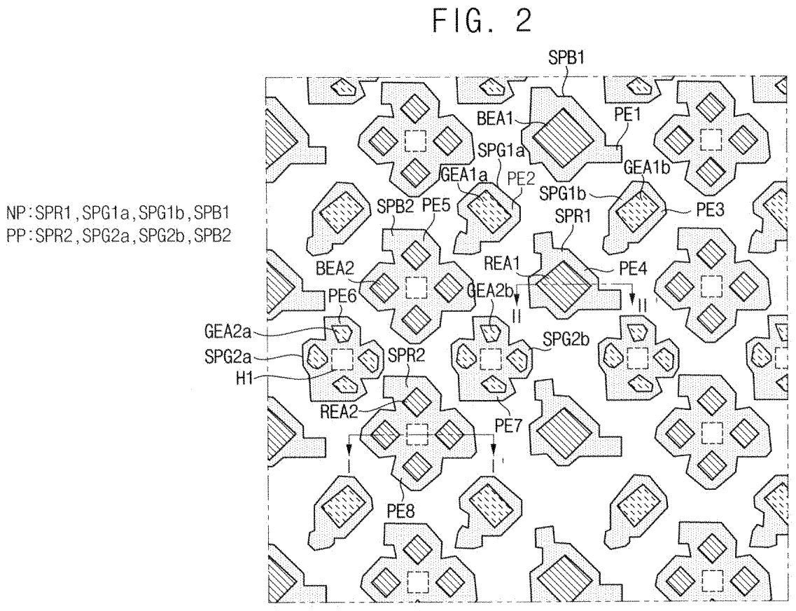

FIG. 2 is a plan view illustrating an embodiment of pixels disposed on a display panel of the display device of FIG. 1.

Referring to FIGS. 1 and 2, the pixel P may include a normal pixel NP and a special pixel PP. The normal pixel NP may include a first red sub pixel SPR1, a first blue sub pixel SPB1, a 1-a-th green sub pixel SPG1a, and a 1-b-th green sub pixel SPG1b. The special pixel PP may include a second red sub pixel SPR2, a second blue sub pixel SPB2, a 2-a-th green sub pixel SPG2a, and a 2-b-th green sub pixel SPG2b.

The normal pixel NP and the special pixel PP may be disposed adjacent to each other, and the normal pixel NP and the special pixel PP may be alternately disposed. That is, the normal pixels NP may be disposed to be spaced apart from each other by the special pixel PP, and the special pixels PP may be disposed to be spaced apart from each other by the normal pixel NP.

In an embodiment, the first blue sub pixel SPB1 in the normal pixel NP may include a first pixel electrode PE1. At least a partial area of the first pixel electrode PE1 may be a light emitting area which emits light. For example, the first blue sub pixel SPB1 may emit light from a first blue light emitting area BEA1. The first blue light emitting area BEA1 may refer to an area in which the first pixel electrode PE1 and a light emitting layer thereof contact each other.

The 1-a-th green sub pixel SPG1a in the normal pixel NP may include a second pixel electrode PE2. At least a partial area of the second pixel electrode PE2 may be a light emitting area which emits light. For example, the 1-a-th green sub pixel SPG1a may emit light from a 1-a green light emitting area GEA1a. The 1-a-th green light emitting area GEA1a may refer to an area in which the second pixel electrode PE2 and a light emitting layer thereof contact each other.

The 1-b-th green sub pixel SPG1b in the normal pixel NP may include a third pixel electrode PE3. At least a partial area of the third pixel electrode PE3 may be a light emitting area which emits light. For example, the 1-b-th green sub pixel SPG1b may emit light from a 1-b-th green light emitting area GEA1b. The 1-b-th green light emitting area GEA1b may refer to an area in which the third pixel electrode PE3 and a light emitting layer thereof contact each other.

The first red sub pixel SPR1 in the normal pixel NP may include a fourth pixel electrode PE4. At least a partial area of the fourth pixel electrode PE4 may be a light emitting area which emits light. For example, the first red sub pixel SPR1 may emit light from a first red light emitting area REAL The first red light emitting area REA1 may refer to an area in which the fourth pixel electrode PE4 and a light emitting layer thereof contact each other.

The second blue sub pixel SPB2 in the special pixel PP may include a fifth pixel electrode PE5. At least a partial area of the fifth pixel electrode PE5 may be a light emitting area which emits light. In this case, the number of the light emitting area may be at least one. For example, as illustrated in FIG. 2, the second blue sub pixel SPB2 may emit light from four second blue light emitting areas BEA2. The second blue light emitting area BEA2 may refer to an area in which the fifth pixel electrode PE5 and the light emitting layer thereof contact each other.

The 2-a-th green sub pixel SPG2a in the special pixel PP may include a sixth pixel electrode PE6. At least a partial area of the sixth pixel electrode PE6 may be a light emitting area which emits light. In this case, the number of the light emitting area may be at least one. For example, as illustrated in FIG. 2, the 2-a-th green sub pixel SPG2a may emit light from four 2-a-th green light emitting areas GEA2a. The 2-a-th green light emitting area GEA2a may refer to an area in which the sixth pixel electrode PE6 and the light emitting layer thereof contact each other.

The 2-b-th green sub pixel SPG2b in the special pixel PP may include a sixth pixel electrode PE7. At least a partial area of the sixth pixel electrode PE7 may be a light emitting area which emits light. In this case, the number of the light emitting area may be at least one. For example, as illustrated in FIG. 2, the 2-b-th green sub pixel SPG2b may emit light from four 2-b-th green light emitting areas GEA2b. The 2-b-th green light emitting area GEA2b may refer to an area in which the sixth pixel electrode PE7 and the light emitting layer thereof contact each other.

The second red sub pixel SPR2 in the special pixel PP may include an eighth pixel electrode PE8. At least a partial area of the eighth pixel electrode PE8 may be a light emitting area which emits light. In this case, the number of the light emitting area may be at least one. For example, as illustrated in FIG. 2, the second red sub pixel SPR2 may emit light from four second red light emitting areas REA2. The second red light emitting area REA2 may refer to an area in which the eighth pixel electrode PE8 and the emission layer thereof contact each other.

In an embodiment, in the special pixel PP, the light emitting areas BEA2, GEA2a, GEA2b, and REA2 may be separated from each other. However, in order to maintain the luminance of the display device, the sum of the areas of the light emitting areas BEA2, GEA2a, GEA2b, and REA2 of the special pixel PP may be substantially equal to the area of the light emitting areas BEA1, GEA1a, GEA1b and REA1 of the normal pixel NP. For example, the areas of the light emitting areas which emit of the same color may be equal to each other.

In this case, each of an area of the pixel electrodes PE5, PE6, PE7, and PE8 of the special pixel PP may be larger than each of an area of the pixel electrodes PE1, PE2, PE3 and PE4 of the normal pixel PP. Accordingly, a sum of the areas of the light emitting areas BEA2, GEA2a, GEA2b and REA2 of the special pixel PP may be substantially equal to a sum of the area of the light emitting areas BEA1, GEA1a, GEA1b and REA1 of the normal pixel NP.

However, as the area of the pixel electrodes PE5, PE6, PE7, and PE8 of the special pixel PP increases, a gas generated in a process of forming a via-insulating layer and a pixel defining layer (See FIG. 7) may not be easily discharged. In this case, the light emitting layer may not normally emit light due to the gas that has not been discharged. To prevent this, in an embodiment, a first opening H1 may be formed (i.e., defined) in the pixel electrodes PE5, PE6, PE7, and PE8 of the special pixel PP. Accordingly, gas generated in the process of forming the via-insulating layer and the pixel defining layer may escape through the first opening H1.

The first opening H1 may be defined in a central area of the pixel electrodes PE5, PE6, PE7, and PE8 of the special pixel PP, respectively. The first opening H1 may be defined within a range that does not separate each of the pixel electrodes PE5, PE6, PE7, and PE8 of the special pixel PP, as shown in FIG. 2, for example. That is, for example, the eighth pixel electrode PE8 is formed in one body with the first opening H1 in the center thereof. Accordingly, the same signal may be simultaneously transmitted to each of the pixel electrodes PE5, PE6, PE7, and PE8 of the special pixel PP. For example, the same light may be simultaneously emitted from the four second red light emitting areas REA2 by a signal transmitted to the eighth pixel electrode PE8.

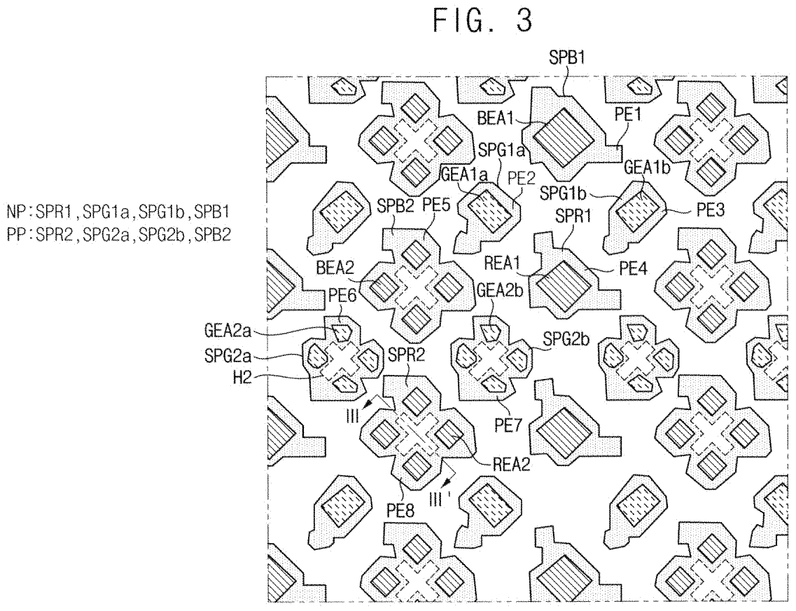

FIGS. 3, 4 and 5 are plan views illustrating other embodiments of pixels disposed on a display panel of the display device of FIG. 1. FIGS. 3, 4, and 5 may be substantially the same as those of FIG. 2 except for the shapes of openings defined in the pixel electrodes of the special pixel. Accordingly, a description of the overlapping configuration will be omitted.

Referring to FIG. 3, a second opening H2 may be defined in each of the pixel electrodes PE5, PE6, PE7, and PE8 of the special pixel PP. The second opening H2 may have a cross shape. Through this, a gas generated in the process of forming the via-insulating layer and the pixel defining layer may be discharged through the second opening H2.

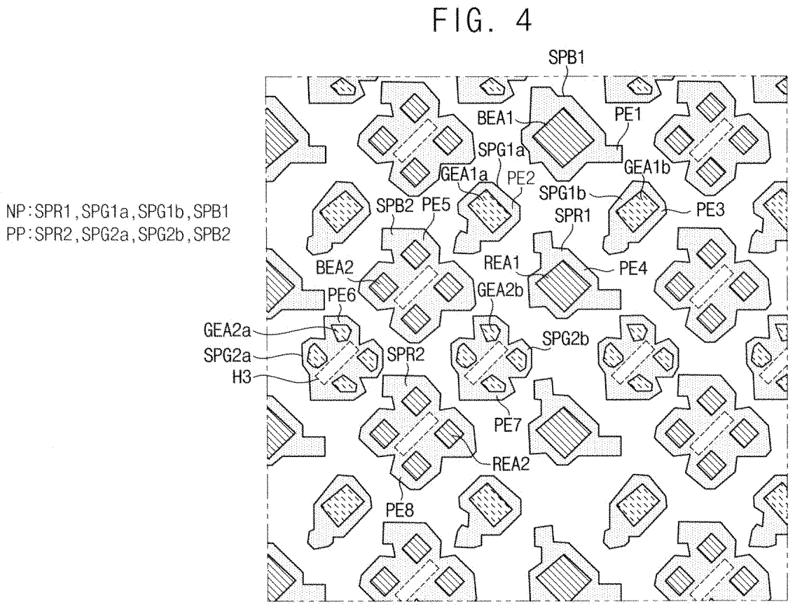

Referring to FIG. 4, a third opening H3 may be defined in each of the pixel electrodes PE5, PE6, PE7, and PE8 of the special pixel PP. The third opening H3 may be formed to extend in one direction. Through this, a gas generated in the process of forming the via-insulating layer and the pixel defining layer may be discharged through the third opening H3.

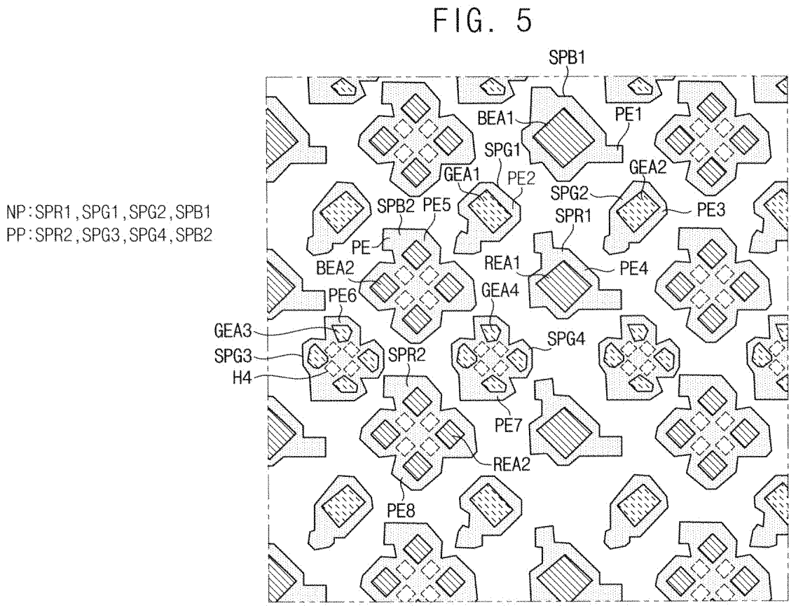

Referring to FIG. 5, a fourth opening H4 may be defined in each of the pixel electrodes PE5, PE6, PE7, and PE8 of the special pixel PP. At least one fourth opening H4 may be defined in each of the pixel electrodes PE5, PE6, PE7, and PE8. For example, as illustrated in FIG. 5, four fourth openings H4 may be defined to be spaced apart from each other in one pixel electrode. Through this, a gas generated in the process of forming the via-insulating layer and the pixel defining layer may be discharged through the fourth opening H4. Even though FIGS. 2 to 5, illustrates a cross shape, a square, a shape extending in one direction as the shape of the openings, the invention is not limited thereto. Alternatively, the opening may have any shape such as a polygonal shape, a circular shape, an oval shape in a plan view.

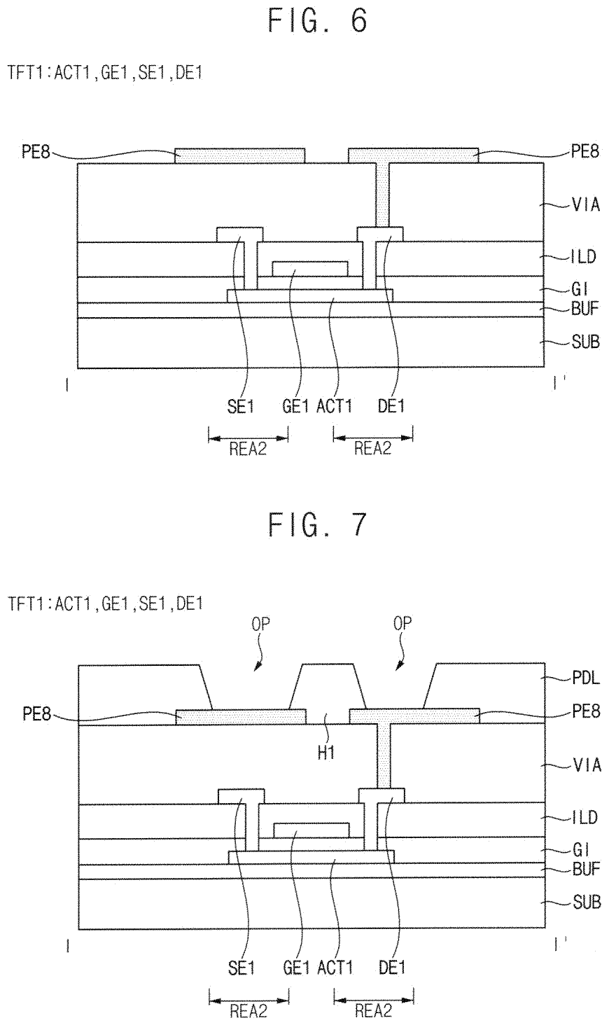

FIG. 6 is a cross-sectional view showing an embodiment taken along line I-I′ of FIG. 2.

Referring to FIGS. 2 and 6, the display device may include a substrate SUB, a buffer layer BUF, a gate insulating layer GI, an interlayer-insulating layer ILD, an eighth pixel electrode PE8 and a first transistor TFT1. The first transistor may include a first active layer ACT1, a first gate electrode GE1, a first source electrode SE1 and a first drain electrode DE1.

The substrate SUB may include glass or plastic. For example, the substrate SUB may include glass, and accordingly, the substrate SUB may have a rigid characteristic. Alternatively, the substrate SUB may include plastic, and accordingly, the substrate SUB may have a flexible characteristic. In addition to this, the substrate SUB may include various materials.

The buffer layer BUF may be disposed on the substrate SUB. The buffer layer BUF may prevent a foreign material penetrating through the substrate SUB from being transferred to the first transistor TFT1. Also, the buffer layer BUF may serve to improve the flatness of the substrate SUB, and accordingly, the buffer layer BUF may form a uniform plane on which the first transistor TFT1 is disposed. The buffer layer BUF may include an inorganic insulating material.

The first active layer ACT1 may be disposed on the buffer layer BUF. The first active layer ACT1 may include a silicon-based semiconductor material or an oxide-based semiconductor material.

The gate insulating layer GI may cover the first active layer ACT1 and may be disposed on the buffer layer BUF. The gate insulating layer GI may insulate the first active layer ACT1 from the first gate electrode GE1. The gate insulating layer GI may include an inorganic insulating material.

The first gate electrode GE1 may be disposed on the gate insulating layer GI. The first gate electrode GE1 may be disposed to overlap the first active layer ACT1 in a plan view. The first gate electrode GE1 may include a conductive material, and a gate signal may be applied thereto. When a gate signal is applied to the first gate electrode GE1, the first active layer ACT1 may be activated. In this case, a signal transmitted through the first source electrode SE1 may flow to the first drain electrode DE1 through the first active layer ACT1.

The interlayer-insulating layer ILD may cover the first gate electrode GE1 and may be disposed on the gate insulating layer GI. The interlayer-insulating layer ILD may insulate the first gate electrode GE1 from the first source electrode SE1 and the first drain electrode DE1. The interlayer-insulating layer ILD may include an inorganic insulating material.

The first source electrode SE1 and the first drain electrode DE1 may be disposed on the interlayer-insulating layer ILD. The first source electrode SE1 may contact the first active layer ACT1 through a contact hole, and the first drain electrode DE1 may also contact the first active layer ACT1 through a contact hole. The first source electrode SE1 and the first drain electrode DE1 may include a conductive material.

In embodiments, the insulating layer may be a via-insulating layer VIA. The via-insulating layer VIA may cover the first source electrode SE1 and the first drain electrode DE1 and may be disposed on the interlayer-insulating layer ILD. The via-insulating layer VIA may include an organic insulating material. The via-insulating layer VIA may be subjected to a planarization process to have a flat top surface on which the light emitting element is disposed. Also, the via-insulating layer VIA may insulate the eighth pixel electrode PE8 from the first source electrode SE1, and the first drain electrode DE1.

The eighth pixel electrode PE8 may be disposed on the via-insulating layer VIA. The eighth pixel electrode PE8 may include a conductive material. The eighth pixel electrode PE8 may be connected to the first drain electrode DE1 through a contact hole. Although the eighth pixel electrodes PE8 are illustrated as being disconnected from each other in FIG. 6, referring to FIG. 2, the eighth pixel electrodes PE8 may be connected to each other. Accordingly, a signal transmitted through the first transistor TFT1 may be transmitted to the eighth pixel electrode PE8 as a whole. A first opening H1 may be defined in a central area of the eighth pixel electrode PE8.

In embodiments, a baking process may be performed to remove gas and/or moisture included in the via-insulating layer VIA in the process of forming the via-insulating layer VIA. In this case, when the eighth pixel electrode PE8 covers the top surface of the via-insulating layer VIA without the first opening H1, the gas emitted in the baking process may not be easily discharged.

The eighth pixel electrode PE8 included in the special pixel PP has a larger area than each of the pixel electrodes included in the normal pixel NP in a plan view, and thus may cover the top surface of the via-insulating layer VIA in a large area. Accordingly, the gas emitted in the baking process by the eighth pixel electrode PE8 may not be easily released without an opening.

Accordingly, the flatness of the eighth pixel electrode PE8 may not be maintained. That is, the eighth pixel electrode PE8 may protrude upward by the pressure of the emitted gas. Accordingly, the light emitting layer disposed on the eighth pixel electrode PE8 may not normally emit light.

However, in the display device according to an embodiment, as the first opening H1 is defined in the eighth pixel electrode PE8, the gas may be easily discharged through the first opening H1. Accordingly, the light emitting layer disposed on the eighth pixel electrode PE8 may be formed to be flat, and light may be normally emitted.

FIG. 7 is a cross-sectional view showing an embodiment taken along line I-I′ of FIG. 2. FIG. 7 may be substantially the same as FIG. 6, except that a pixel defining layer is additionally formed in FIG. 6. A description of the overlapping configuration will be omitted.

Referring to FIGS. 2 and 7, the display device may further include a pixel defining layer PDL. The pixel defining layer PDL may be disposed on the via-insulating layer VIA to partially cover the eighth pixel electrode PE8. The pixel defining layer PDL may define at least one opening OP exposing the eighth pixel electrode PE8.

The pixel defining layer PDL may serve to separate the eighth pixel electrode PE8 from other pixel electrodes. For example, the eighth pixel electrode PE8 may be disconnected from the adjacent fifth pixel electrode PE5, the sixth pixel electrode PE6, and the seventh pixel electrode PE7 by the pixel defining layer PDL. The fifth pixel electrode PE5, the sixth pixel electrode PE6, and the seventh pixel electrode PE7 may also be separated from each other by the pixel defining layer PDL.

Also, the pixel defining layer PDL may separate the plurality of second red light emitting areas REA2 on the eighth pixel electrode PE8. In this case, the pixel defining layer PDL may be disposed to fill the first opening H1.

The pixel defining layer PDL may include an organic insulating material. In embodiments, the pixel defining layer PDL may be formed of or include the same material as the via-insulating layer VIA. Accordingly, the pixel defining layer PDL may also include gas and/or moisture. The baking process may be performed to remove gas and/or moisture included in the pixel defining layer PDL.

The baking process may be performed after the via-insulating layer VIA is formed, and may be performed once again after the pixel defining layer PDL is formed. Alternatively, the baking process may be performed after both the via-insulating layer VIA and the pixel defining layer PDL are formed.

When the baking process is performed on the pixel defining layer PDL, gas and/or moisture included in the via-insulating layer VIA may be discharged to the outside through the pixel defining layer PDL. Accordingly, gas and/or moisture included in the via-insulating layer VIA may also escape through the pixel defining layer PDL disposed in the first opening H1.

If the first opening H1 is not formed in the eighth pixel electrode PE8 of the special pixel PP having an area larger than an area of each of the pixel electrodes of the normal pixel NP, the pressure is caused by the emitted gas and/or moisture. Accordingly, the eighth pixel electrode PE8 may not be flatly disposed and may protrude upward.

Although the eighth pixel electrode PE8 has been described as an example in the above description, the first opening H1 may also be defined in the pixel electrodes PE5, PE6, and PE7 of the special pixel PP.

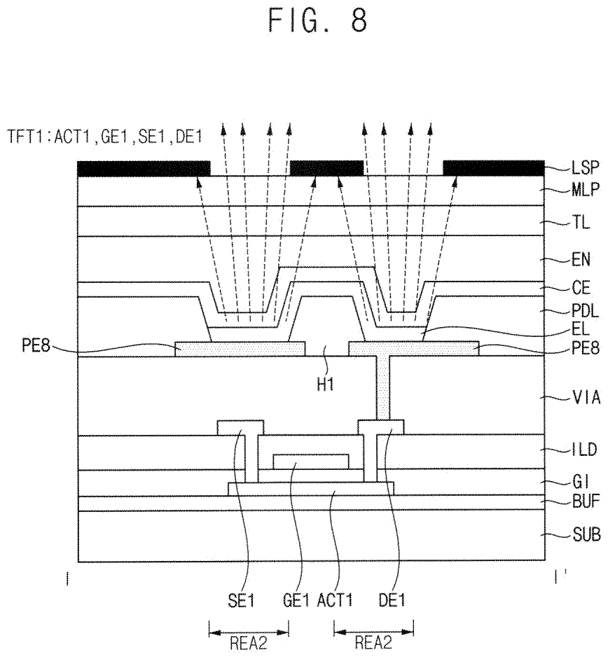

FIG. 8 is a cross-sectional view showing an embodiment taken along line I-I′ of FIG. 2. FIG. 8 may be substantially the same as FIG. 7, except that some components are added. Accordingly, a description of the overlapping configuration will be omitted.

Referring to FIGS. 2 and 8, the display device may further include a light emitting layer EL, a common electrode CE, an encapsulation layer EN, a touch sensing layer TL, a light collecting layer MLP, and a light blocking pattern LSP.

The encapsulation layer EN may be disposed on the common electrode CE. The encapsulation layer EN may cover the common electrode CE and may protect components disposed under the encapsulation layer EN from external impurities.

In embodiments, the encapsulation layer EN may include at least one inorganic encapsulation layer and at least one organic encapsulation layer. For example, the encapsulation layer EN may include a first inorganic encapsulation layer, an organic encapsulation layer disposed on the first inorganic encapsulation layer, and a second inorganic encapsulation layer disposed on the organic encapsulation layer.

In embodiments, the encapsulation layer EN may include glass. For example, an encapsulation layer EN made of a glass frit may be disposed on the common electrode CE. In this case, an empty space may be defined between the encapsulation layer EN and the common electrode CE.

In an embodiment, the touch sensing layer TL may be disposed on the encapsulation layer EN. The touch sensing layer TL may sense a user's touch or non-contact touch. For example, the touch sensing layer TL may sense a user's touch in a capacitive manner. As a specific example, the touch sensing layer TL may sense a user's touch using a self-capacitance method or a mutual capacitance method. In another embodiment, the touch sensing layer TL may be omitted.

In an embodiment, a light collecting layer MLP may be disposed on the touch sensing layer TS. For example, the light collecting layer MLP may include a plurality of micro lenses. Accordingly, the light path of the light emitted from the light emitting layer EL may be focused in a predetermined direction. In another embodiment, the light collection layer MLP may be omitted.

In an embodiment, a light blocking pattern LSP may be disposed on the light collection layer MLP. The light blocking pattern LSP may be disposed to overlap the pixel defining layer PDL in a plan view. The light blocking pattern LSP may be disposed to expose the second red light emitting areas REA2 in a plan view. Accordingly, light emitted from the light emitting layer EL may be emitted between the light blocking patterns LSP. In this case, some of the emitted light may be blocked by the light blocking pattern LSP, and accordingly, the light emitted from the special pixel PP may be emitted with a narrow viewing angle. The light blocking pattern LSP may be formed of or include a material capable of blocking light. For example, in embodiments, the light blocking pattern LSP may be a black matrix. The black matrix may be formed of or include chromium (“Cr”), chromium oxide (“CrOx”), chromium nitride (“CrNx”), carbon black, a pigment mixture, a dye mixture, or the like.

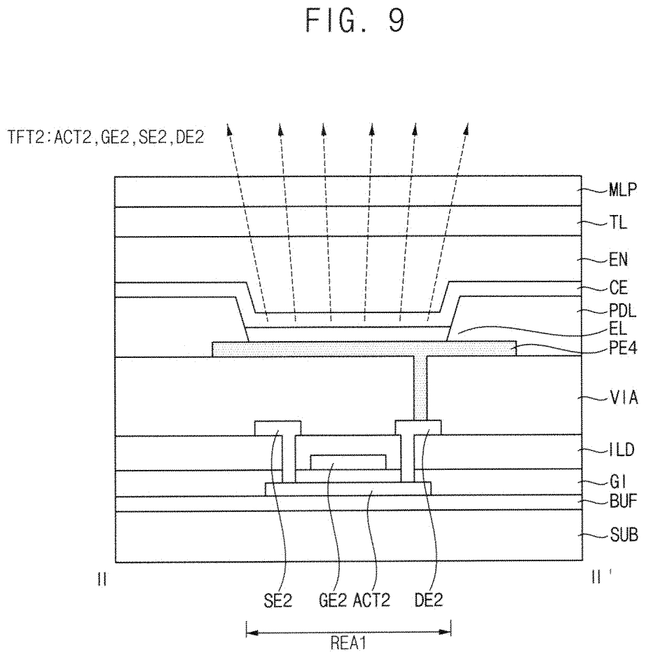

FIG. 9 is a cross-sectional view showing an embodiment taken along line II-II′ of FIG. 2. FIG. 9 may be substantially the same as FIG. 8 except that a light blocking pattern is not disposed. Accordingly, a description of the overlapping configuration will be omitted.

Referring to FIGS. 2 and 9, the display device may include a substrate SUB, a buffer layer BUF, a gate insulating layer GI, an interlayer-insulating layer ILD, a via-insulating layer VIA, a second transistor TFT2, a pixel defining layer PDL, a fourth pixel electrode PE4, a light emitting layer EL, a common electrode CE, an encapsulation layer EN, a touch sensing layer TL, and a light collecting layer MLP. The second transistor TFT2 may include a second active layer ACT2, a second gate electrode GE2, a second source electrode SE2, and a second drain electrode DE2.

The second active layer ACT2 may be activated by a signal applied to the second gate electrode GE2. In this case, when the second active layer ACT2 is activated, a signal transmitted through the second source electrode SE2 may be transmitted to the second drain electrode DE2 through the second active layer ACT2.

A signal transmitted from the second transistor TFT2 may be transmitted to the fourth pixel electrode PE4. Accordingly, light may be emitted from the first red light emitting area REA1.

The light emitting area of the first red sub pixel SPR1 constituting the normal pixel NP may not be divided. Accordingly, the area of the fourth pixel electrode PE4 does not need to be increased in order to secure the same light emitting area. Therefore, unlike the aforementioned eighth pixel electrode PE8, the fourth pixel electrode PE4 may not include an opening.

FIGS. 6, 7, 8 and 9 have been described with reference to the red sub pixels SPR1 and SPR2, but this is exemplary and the invention is not limited thereto. The above descriptions may be equally applied to the blue sub pixels SPB1 and SPB2 and the green sub pixels SPG1a and SPG1b.

In addition, since the normal pixel NP does not need to have a narrow viewing angle, the light blocking pattern LSP may not be separately disposed. However, in embodiments, the light blocking pattern LSP may also be disposed on the normal pixel NP, if necessary.

When only the special pixel PP is driven, the display device may display an image to have a narrow viewing angle. Also, when the special pixel PP and the normal pixel NP are simultaneously driven, the display device may display an image to have a relatively wider viewing angle than when only the special pixel PP is driven.

FIG. 10 is a cross-sectional view showing an embodiment taken along line of FIG. 3.

Referring to FIGS. 3 and 10, the display device may include a substrate SUB, a buffer layer BUF, a third transistor TFT3, a gate insulating layer GI, an interlayer-insulating layer ILD, a via-insulating layer VIA, and an eighth pixel electrode PE8. The third transistor TFT3 may include a third active layer ACT3, a third gate electrode GE3, a third source electrode SE3, and a third drain electrode DE3.

The second opening H2 may have a cross shape in the eighth pixel electrode PE8. The second opening H2 has a relatively larger area than the aforementioned first opening H1 in a plan view, so that gas and/or moisture may be effectively discharged through the second opening H2.

As illustrated in FIG. 3, even when the second hole H2 is formed, the eighth pixel electrode PE8 may not be cut. Accordingly, when a signal is applied to the eighth pixel electrode PE8, the same light may be simultaneously emitted from the second red light emitting areas REA2.

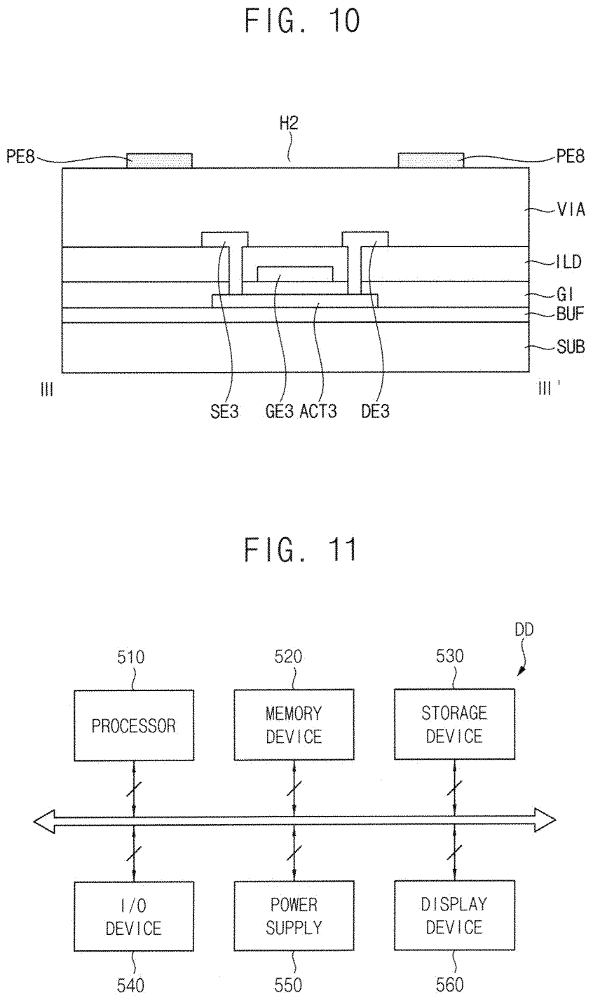

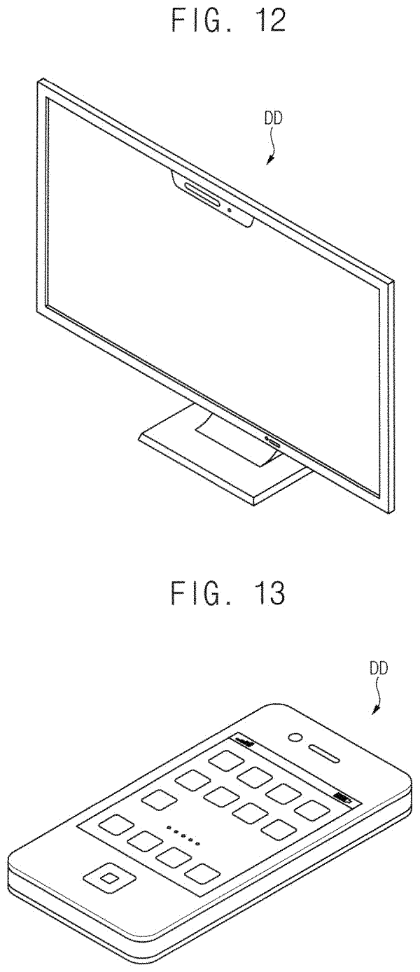

FIG. 11 is a block view illustrating an electronic device according to an embodiment, FIG. 12 is a diagram view an example in which the electronic device of FIG. 11 is implemented as a television and FIG. 13 is a diagram illustrating an example in which the electronic device of FIG. 11 is implemented as a smartphone.

Referring to FIGS. 11, 12 and 13, an electronic device DD may include a processor 510, a memory device 520, a storage device 530, an input/output device 540, a power supply 550, and a display device 560. In this case, the display device 560 may correspond to the display device described with reference to the aforementioned drawings. The electronic device DD may further include several ports capable of communicating with a video card, a sound card, a memory card, a USB device, and the like. In an embodiment, as illustrated in FIG. 12, the electronic device DD may be implemented as a television. In another embodiment, as illustrated in FIG. 13, the electronic device DD may be implemented as a smartphone. However, the electronic device DD according to the invention is not limited thereto, and for example, the electronic device DD includes a mobile phone, a video phone, a smart pad, a smart watch, a tablet PC, a vehicle navigation system, It may be implemented as a computer monitor, notebook computer, head mounted display (“HMD”), or the like.

The processor 510 may perform specific calculations or tasks. In an embodiment, the processor 510 may be a micro processor, a central processing unit (“CPU”), an application processor (“AP”), or the like. The processor 510 may be connected to other components through an address bus, a control bus, a data bus, or the like. In an embodiment, the processor 510 may also be connected to an expansion bus such as a peripheral component interconnect (“PCI”) bus.

The memory device 520 may store data necessary for the operation of the electronic device DD. For example, the memory device 520 may include nonvolatile memory device such as an erasable programmable read-only memory (“EPROM”) device, an electrically erasable programmable read-only memory (“EEPROM”) device, a flash memory device, and a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and/or volatile memory device such as a dynamic random access memory (“DRAM”) device, a static random access memory (“SRAM”) device, a mobile DRAM device.

The storage device 530 may include a solid state drive (“SSD”), a hard disk drive (“HDD”), a CD-ROM, or the like. The input/output device 540 may include an input means such as a keyboard, a keypad, a touch pad, a touch screen, and a mouse, and an output means such as a speaker and a printer.

The display device according to the embodiments may be applied to a display device included in a computer, a notebook, a mobile phone, a smartphone, a smart pad, a PMP, a PDA, an MP3 player, or the like.

Although the display devices according to the embodiments have been described with reference to the drawings, the illustrated embodiments are examples, and may be modified and changed by a person having ordinary knowledge in the relevant technical field without departing from the technical spirit of the disclosure. Accordingly, the scope of the disclosure should not be limited by the disclosed embodiments, but rather should be interpreted in accordance with the following claims including their equivalents.

What is claimed is:

1. A display device, comprising:
a first transistor;
an insulating layer disposed on the first transistor;
a first pixel electrode which is connected to the first transistor and disposed on the insulating layer and defines a first opening exposing the insulating layer therein;
a pixel defining layer disposed on the first pixel electrode and defining a plurality of second openings exposing the first pixel electrode therein; and
a first light emitting layer disposed on the pixel defining layer to fill the plurality of second openings.

2. The display device of claim 1, wherein the pixel defining layer is disposed to fill the first opening.

3. The display device of claim 1, further comprising:
a second transistor;
a second pixel electrode connected to the second transistor and disposed on the insulating layer disposed on the second transistor, wherein the second pixel electrode does not define an opening exposing the insulating layer therein; and
a second light emitting layer disposed on the second pixel electrode.

4. The display device of claim 3, wherein the pixel defining layer is disposed on the second pixel electrode and define a third opening exposing the second pixel electrode therein, and
wherein the second light emitting layer is disposed in the third opening.

5. The display device of claim 4, wherein the first light emitting layer and the second light emitting layer emit light of a same color, and
wherein a size of an area in which the first light emitting layer contacts the first pixel electrode is the same as a size of an area in which the second light emitting layer contacts the second pixel electrode.

6. The display device of claim 3, further comprising:
a common electrode disposed on the first light emitting layer and the second light emitting layer; and
an encapsulating layer disposed on the common electrode.

7. The display device of claim 3, wherein areas in which the first pixel electrode and the first light emitting layer contact form light emitting areas, and
wherein the display device further comprises a light blocking pattern disposed to expose the light emitting areas in a plan view.

8. The display device of claim 7, wherein the light blocking pattern is disposed to overlap the first opening in the plan view.

9. The display device of claim 7, wherein the light emitting areas emit light of a same color.

10. The display device of claim 1, further comprising:
a second transistor;
a second pixel electrode which is connected to the second transistor and disposed on the insulating layer disposed on the second transistor and defines a third opening exposing the insulating layer therein; and
a second light emitting layer disposed on the second pixel electrode.

11. The display device of claim 10, wherein the pixel defining layer is disposed on the second pixel electrode and defines a plurality of fourth openings exposing the second pixel electrode therein, and
wherein the second light emitting layer is disposed to fill the fourth openings.

12. The display device of claim 11, wherein the pixel defining layer is disposed to fill the third opening.

13. The display device of claim 10, wherein the first light emitting layer and the second light emitting layer emit light of a same color.

14. The display device of claim 10, wherein the first light emitting layer and the second light emitting layer emit light of different colors.

15. The display device of claim 1, wherein the first pixel electrode receives a signal for driving the first light emitting layer from the first transistor.

16. The display device of claim 1, wherein the first opening has a polygonal shape or a circular shape in a plan view.

17. The display device of claim 1, wherein the first opening has a cross shape in a plan view.

18. The display device of claim 1, wherein the first opening has a shape extending in one direction in a plan view.

19. The display device of claim 1, wherein the first opening is provided in plural.
